(19) United States
(12) Patent Application Publication
(10) Pub. No.: US 2025/0192065 A1
(43) Pub. Date: Jun. 12, 2025

(54) SEMICONDUCTOR DEVICE

(71) Applicant: Mitsubishi Electric Corporation, Tokyo (JP)

(72) Inventor: Haruki MURAKAMI, Tokyo (JP)

(73) Assignee: Mitsubishi Electric Corporation, Tokyo (JP)

(21) Appl. No.: 18/808,639

(22) Filed: Aug. 19, 2024

(30) Foreign Application Priority Data
Dec. 11, 2023 (JP) 2023-208520

(51) Int. Cl. H01L 23/544; H01L 23/13; H01L 23/367

(52) U.S. Cl. CPC H01L 23/544; H01L 23/13; H01L 23/367; H01L 2223/54426

(57) ABSTRACT

A semiconductor device according to the present disclosure includes a semiconductor module and a base plate on which the semiconductor module is mounted. The semiconductor module includes a linear protrusion that is provided so as not to be point-symmetric with respect to a center of the semiconductor module on at least one side, and the base plate includes a recess that is provided so as to correspond to the protrusion.

### BACKGROUND OF THE INVENTION

### Field of the Invention

The present disclosure relates to a semiconductor device, and particularly to a power semiconductor device.

### Description of the Background Art

In general, a power semiconductor module represented by an insulated gate bipolar transistor (IGBT) module, an intelligent power module (IPM), a transfer molded power module (T-PM), or the like is connected to a cooler through a base plate in order to dissipate heat generated by power loss. Connection between the power semiconductor module and the cooler is implemented by fitting a protrusion (projection) provided in the power semiconductor module into a recess (recess corresponding to the protrusion of the semiconductor module) provided in the cooler. With such a configuration, because the semiconductor module is positioned with respect to the cooler, positional displacement of the semiconductor module in the horizontal direction can be prevented during assembling the semiconductor module or during solder reflow.

On the other hand, for the semiconductor modules having the same outer shape but different types (functions), when the protrusions provided in the respective semiconductor modules are provided at the same position, the protrusions can be fitted into recesses (recesses corresponding to the protrusions of the semiconductor modules) provided in the cooler, so that it is difficult to prevent erroneous mounting of the semiconductor modules. At this point, for example, the semiconductor modules having the same outer shape but different types (functions) refer to semiconductor modules having different rated currents, rated voltages, or circuit configurations.

Conventionally, there has been disclosed a technique for preventing the semiconductor module from being erroneously mounted in a region other than a region where the semiconductor module is to be mounted by making a distance between a pair of protrusions provided in the semiconductor module different according to a size of the semiconductor module (see, for example, WO 2018/131310 A).

In WO 2018/131310 A, although the distance between the protrusions is made different according to the size of the semiconductor module, because the type cannot be identified for semiconductor modules having the same outer shape and different types, there is a problem that the semiconductor module of the type different from the original type can be erroneously mounted. In addition, in WO 2018/131310 A, because the pair of protrusions is provided in the semiconductor module, there is a problem that the semiconductor module can be erroneously mounted in the opposite direction (a direction different from the original direction by 180 degrees).

### SUMMARY

An object of the present disclosure is to provide a semiconductor device that achieves both positioning of the semiconductor module and prevention of erroneous mounting of the semiconductor module.

A semiconductor device according to the present disclosure includes a semiconductor module and a base plate on which the semiconductor module is mounted. The semiconductor module includes a linear protrusion that is provided so as not to be point-symmetric with respect to a center of the semiconductor module on at least one side, and the base plate includes a recess that is provided so as to correspond to the protrusion.

According to the present disclosure, both the positioning of the semiconductor module and the prevention of the erroneous mounting of the semiconductor module can be achieved.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a view illustrating an example of an overall configuration of a semiconductor device according to first to eighth preferred embodiments;

FIG. 2 is a view illustrating an example of a configuration of a semiconductor module;

FIG. 3 is a view illustrating an example of a configuration of a water-cooling jacket;

FIGS. 4 to 6 are views illustrating an example of a configuration of the semiconductor module according to the first preferred embodiment;

FIG. 7 is a view illustrating an example of a configuration of a base plate according to the first preferred embodiment;

FIG. 8 is a view illustrating a state in which the semiconductor module according to the first embodiment is mounted on the base plate;

FIG. 9 is a view illustrating an example of a configuration of a semiconductor module according to the second preferred embodiment;

FIG. 10 is a view illustrating an example of a configuration of a base plate according to the second preferred embodiment;

FIG. 11 is a view illustrating an example of a configuration of a semiconductor module according to the third preferred embodiment;

FIG. 12 is a view illustrating an example of a configuration of a base plate according to the third preferred embodiment;

FIG. 13 is a view illustrating a state in which a part of a protrusion provided in the semiconductor module according to the first embodiment is lost;

FIG. 14 is a view illustrating an example of a configuration of a semiconductor module according to the fourth preferred embodiment;

FIG. 15 is a view illustrating an example of a configuration of a base plate according to the fourth preferred embodiment;

FIG. 16 is a diagram showing an example of a configuration of a semiconductor module according to the fifth preferred embodiment;

FIG. 17 is a view illustrating an example of a configuration of a base plate according to the fifth preferred embodiment;

FIG. 18 is a view illustrating an example of a configuration of a semiconductor module according to the sixth preferred embodiment;

FIG. 19 is a view illustrating an example of a configuration of a base plate according to the sixth preferred embodiment;

FIG. 20 is a view illustrating an example of a configuration of a semiconductor module according to the seventh preferred embodiment;

FIG. 21 is a view illustrating an example of a configuration of a base plate according to the seventh preferred embodiment;

FIG. 22 is a view illustrating an example of a configuration of a semiconductor module according to the eighth preferred embodiment; and

FIG. 23 is a view illustrating an example of a configuration of a base plate according to the eighth preferred embodiment.

### DESCRIPTION OF THE PREFERRED EMBODIMENTS

### <Entire Configuration>

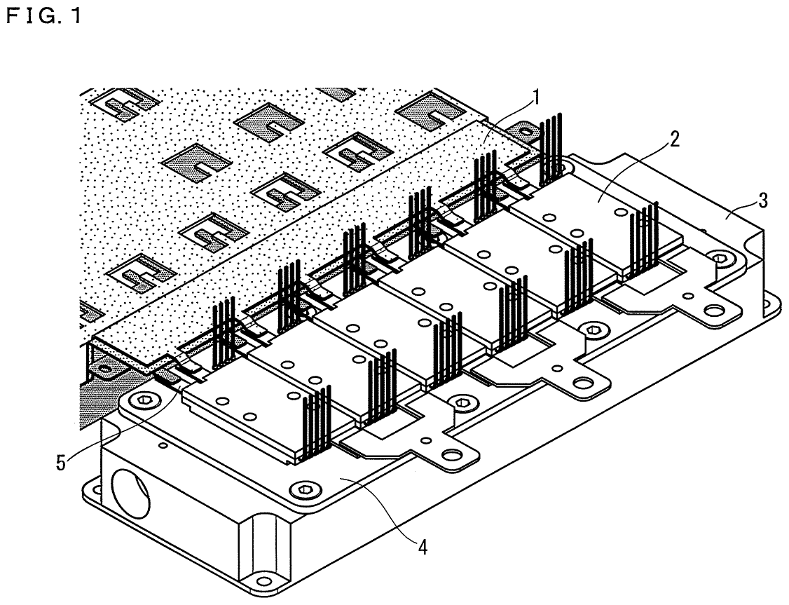

FIG. 1 is a view illustrating an example of an overall configuration of a semiconductor device according to first to eighth preferred embodiments.

The semiconductor device includes at least a semiconductor module 2. The semiconductor device may further include not only the semiconductor module 2 but also at least one of a bus bar 1, a water-cooling jacket 3, and a base plate 4.

In FIG. 1, six semiconductor modules 2 are mounted on the base plate 4, but a number of semiconductor modules 2 is not limited to six. The base plate 4 is provided on the water-cooling jacket 3. That is, the semiconductor module 2 is attached to the water-cooling jacket 3 through the base plate 4.

An electrode terminal 5 is provided in the semiconductor module 2, and the electrode terminal 5 is connected to the bus bar 1.

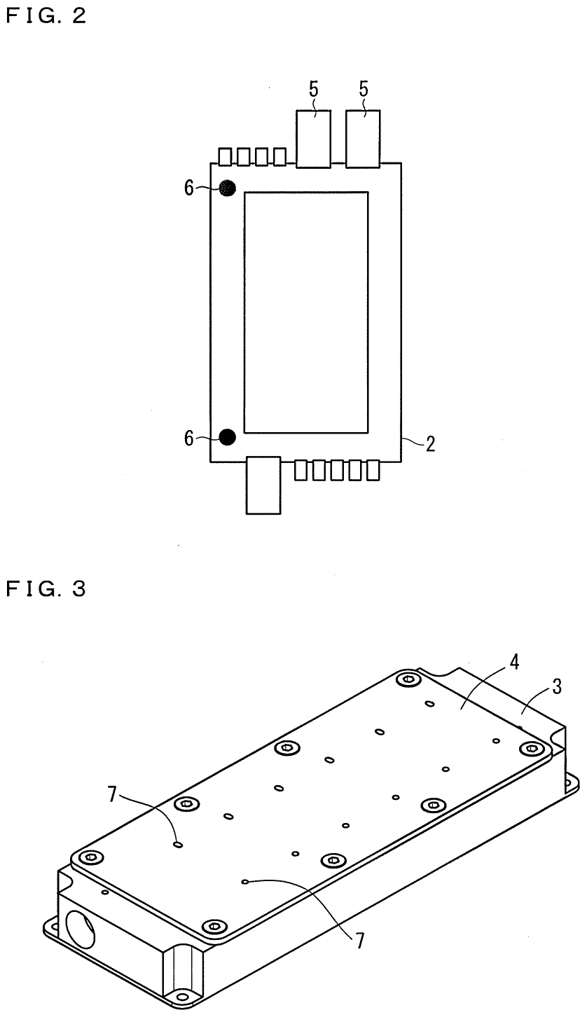

FIG. 2 illustrates a back surface (a surface connected to the base plate 4) of the semiconductor module 2.

The electrode terminal 5 protrudes outward from the semiconductor module 2. A protrusion 6 is provided on at least one side of the semiconductor module 2. The protrusion 6 in FIG. 2 is an example, and a shape, the number, and a position of the protrusion 6 are different in each of first to eighth preferred embodiments.

FIG. 3 is a view illustrating an example of a configuration of the water-cooling jacket 3.

The base plate 4 is attached to the water-cooling jacket 3. A recess 7 is provided on the base plate 4. The protrusion 6 of the semiconductor module 2 is fitted into the recess 7 of the base plate 4. The recess 7 in FIG. 3 is an example, and the shape, the number, and the position of the recess 7 are different in each of the first to eighth preferred embodiments.

### First Preferred Embodiment

### <Configuration>

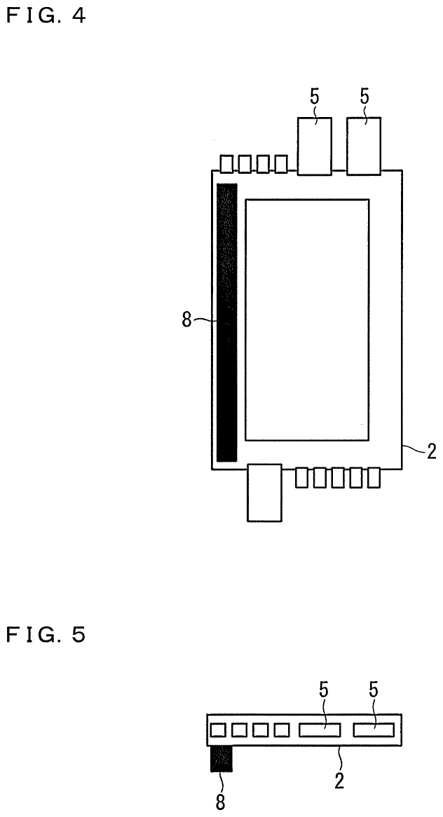

FIG. 4 is a view illustrating an example of a configuration of the semiconductor module 2 according to a first preferred embodiment, and illustrates the back surface of the semiconductor module 2. FIG. 5 is a view illustrating the semiconductor module 2 in FIG. 4 when the semiconductor module 2 is viewed from a side of the electrode terminal 5.

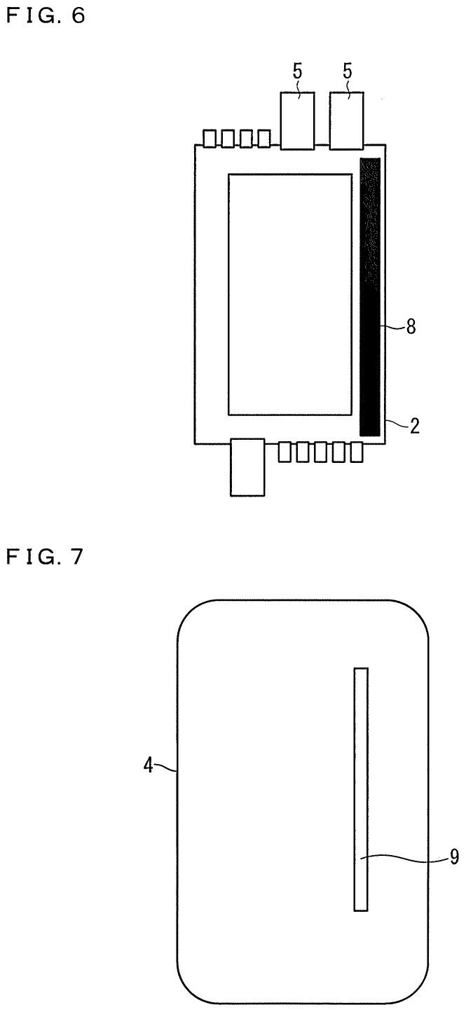

The semiconductor module 2 has a linear protrusion 8 on one side. FIGS. 4 and 5 illustrate a case where the linear protrusion 8 is provided on one side of the semiconductor module 2, but as illustrated in FIG. 6, the linear protrusion 8 may be provided on another side, or the linear protrusion 8 may be provided on a plurality of sides of the semiconductor module 2. That is, the semiconductor module 2 includes the linear protrusion 8 on at least one side.

The linear protrusion 8 is provided so as not to be point-symmetric with respect to a center of the semiconductor module 2 (the center of the semiconductor module 2 in plan view in FIG. 4). The protrusion 8 of the semiconductor module 2 in FIGS. 4 and 5 is provided on one side of the semiconductor module 2, and provided so as not to be point-symmetric with respect to the center of the semiconductor module 2. In addition, when the protrusions 8 are provided on a plurality of sides of the semiconductor module 2, these protrusions 8 are required to be provided so as not to be point-symmetric with respect to the center of the semiconductor module 2.

FIG. 7 is a view illustrating a configuration of the base plate 4. The base plate 4 includes a linear recess 9 that is provided so as to correspond to the protrusion 8 of the semiconductor module 2.

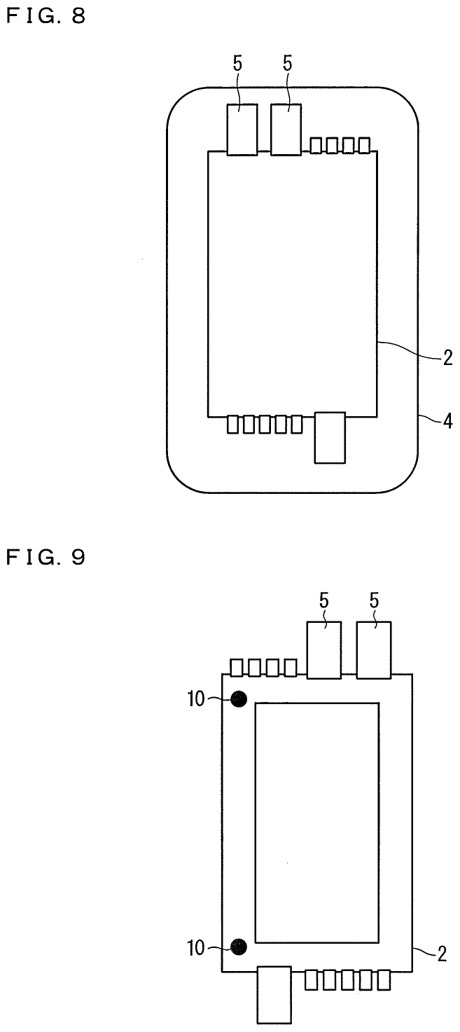

As illustrated in FIG. 8, when the semiconductor module 2 is mounted on the base plate 4, the protrusion 8 of the semiconductor module 2 and the recess 9 of the base plate 4 are fitted to each other. Thus, the semiconductor module 2 is positioned.

### <Effect>

When the protrusion 8 of the semiconductor module 2 and the recess 9 of the base plate 4 are fitted to each other, the semiconductor module 2 and the base plate 4 can be fixed so as not to be displaced (the semiconductor module 2 can be positioned).

In addition, because the protrusion 8 of the semiconductor module 2 is provided so as not to be point-symmetric with respect to the center of the semiconductor module 2, the direction is limited to one direction when the semiconductor module 2 is mounted on the base plate 4 (the direction in which the semiconductor module 2 and the base plate 4 can be fitted is limited to one direction), so that erroneous mounting that the direction in which the semiconductor module 2 is mounted is different from the original direction can be prevented.

As described above, according to the first preferred embodiment, both the positioning of the semiconductor module 2 and the prevention of the erroneous mounting of the semiconductor module 2 can be achieved.

### Second Preferred Embodiment

### <Configuration>

FIG. 9 is a view illustrating an example of a configuration of a semiconductor module 2 according to the second preferred embodiment, and illustrates a back surface of the semiconductor module 2.

The semiconductor module 2 has protrusions 10 at both ends of one side. Both ends of one side correspond to corners of the semiconductor module 2.

Although FIG. 9 illustrates the case where the protrusions 10 are provided at both ends of one side of the semiconductor module 2, the protrusions 10 may also be provided at both ends of a plurality of sides of the semiconductor module 2. That is, the semiconductor module 2 includes the protrusions 10 at both ends of at least one side.

The protrusion 10 is provided so as not to be point-symmetric with respect to the center of the semiconductor module 2 (the center of the semiconductor module 2 in plan view illustrated in FIG. 9). The protrusions 10 of the semiconductor module 2 in FIG. 9 are provided at both ends of one side of the semiconductor module 2, and provided so as not to be point-symmetric with respect to the center of the semiconductor module 2. When the protrusions 10 are provided at both ends of the plurality of sides of the semiconductor module 2, these protrusions 10 are required to be provided so as not to be point-symmetric with respect to the center of the semiconductor module 2.

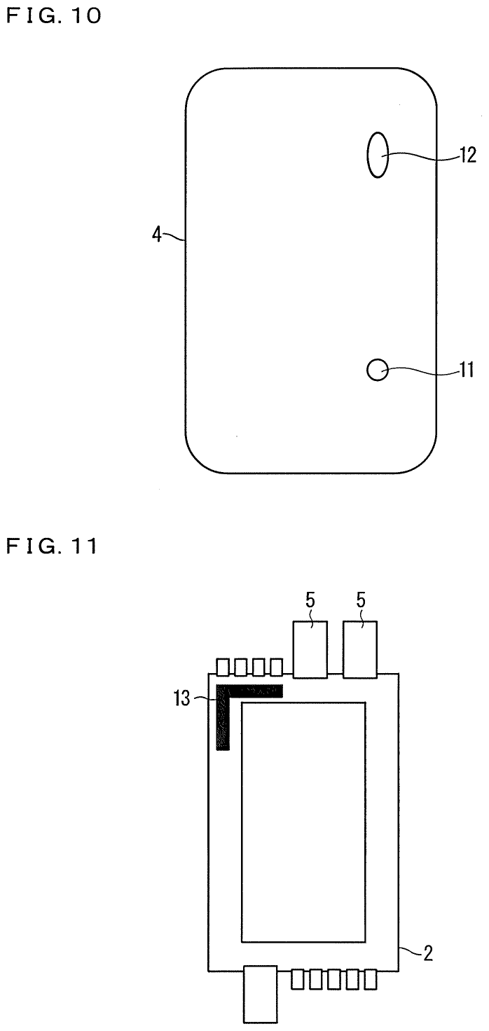

FIG. 10 is a view illustrating a configuration of the base plate 4. The base plate 4 includes a circular recess 11 and an elliptical recess 12 that are provided so as to correspond to the protrusions 10 of the semiconductor module 2. When the semiconductor module 2 is mounted on the base plate 4, the protrusion 10 provided at one end of one side of the semiconductor module 2 and the circular recess 11 of the base plate 4 are fitted to each other, and the protrusion 10 provided at the other end of one side of the semiconductor module 2 and the elliptical recess 12 of the base plate 4 are fitted to each other. Thus, the semiconductor module 2 is positioned.

### <Effect>

In the first preferred embodiment, when the linear protrusion 8 of the semiconductor module 2 is longer than the linear recess 9 of the base plate 4 due to dimensional tolerance of the semiconductor module 2 or the base plate 4, the protrusion 8 of the semiconductor module 2 and the recess 9 of the base plate 4 may not be fitted to each other. When the linear recess 9 of the base plate 4 is longer than the linear protrusion 8 of the semiconductor module 2, positional displacement may be generated when the semiconductor module 2 is mounted on the base plate 4.

On the other hand, in the second preferred embodiment, in the protrusions 10 provided at both ends of one side of the semiconductor module 2, the recess 11 of the base plate 4 corresponding to the protrusion 10 provided at one end is formed in a circular shape to be fitted to the protrusion 10, and the recess 12 of the base plate 4 corresponding to the protrusion 10 provided at the other end is formed in an elliptical shape. Thus, the fitting in consideration of the dimensional tolerance of the semiconductor module 2 or the base plate 4 becomes possible, and the semiconductor module 2 and the base plate 4 can be fixed so as not to be displaced (the semiconductor module 2 can be positioned).

In addition, because the protrusion 10 of the semiconductor module 2 is provided so as not to be point-symmetric with respect to the center of the semiconductor module 2, the direction is limited to one direction when the semiconductor module 2 is mounted on the base plate 4 (the direction in which the semiconductor module 2 and the base plate 4 can be fitted is limited to one direction), so that erroneous mounting that the direction in which the semiconductor module 2 is mounted is different from the original direction can be prevented.

As described above, according to the second preferred embodiment, both the positioning of the semiconductor module 2 and the prevention of the erroneous mounting of the semiconductor module 2 can be achieved.

### Third Preferred Embodiment

### <Configuration>

FIG. 11 is a view illustrating an example of a configuration of a semiconductor module 2 according to the third preferred embodiment, and illustrates a back surface of the semiconductor module 2.

The semiconductor module 2 has an L-shaped protrusion 13 at one corner. Although FIG. 11 illustrates the case where the protrusion 13 is provided at one corner of the semiconductor module 2, the protrusions 13 may be provided at a plurality of corners of the semiconductor module 2. That is, the semiconductor module 2 includes the protrusion 13 at at least one corner.

The protrusion 13 is provided so as not to be point-symmetric with respect to the center of the semiconductor module 2 (the center of the semiconductor module 2 in plan view illustrated in FIG. 11). The protrusion 13 of the semiconductor module 2 in FIG. 11 is provided at one corner of the semiconductor module 2, and provided so as not to be point-symmetric with respect to the center of the semiconductor module 2. In addition, when the protrusions 13 are provided at the plurality of corners of the semiconductor module 2, these protrusions 13 is required to be provided so as not to be point-symmetric with respect to the center of the semiconductor module 2.

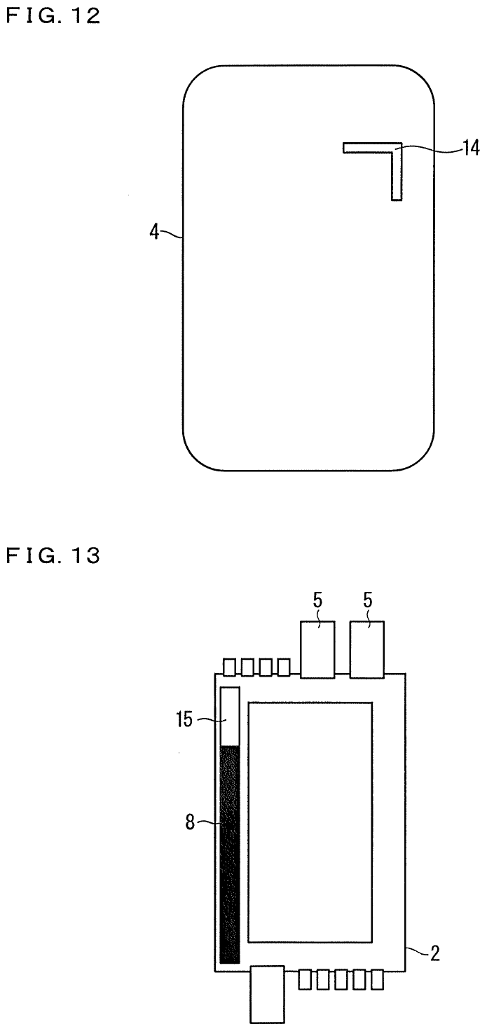

FIG. 12 is a view illustrating a configuration of the base plate 4. The base plate 4 includes an L-shaped recess 14 that is provided so as to correspond to the protrusion 13 of the semiconductor module 2. When the semiconductor module 2 is mounted on the base plate 4, the protrusion 13 provided at the corner of the semiconductor module 2 and the recess 14 of the base plate 4 are fitted to each other. Thus, the semiconductor module 2 is positioned.

### <Effect>

In the first preferred embodiment, when a lost portion 15 in which a part of the linear protrusion 8 is lost is formed as illustrated in FIG. 13, the positional displacement is generated when the semiconductor module 2 is mounted on the base plate 4, so that the semiconductor module 2 and the base plate 4 cannot be fixed so as not to be displaced.

On the other hand, in the third preferred embodiment, because the protrusion 13 of the semiconductor module 2 has an L shape, even when a part of the protrusion 13 is lost, a remaining portion can be fitted into the recess 14 of the base plate 4 (the semiconductor module 2 can be positioned).

In addition, because the protrusion 13 of the semiconductor module 2 is provided so as not to be point-symmetric with respect to the center of the semiconductor module 2, the direction is limited to one direction when the semiconductor module 2 is mounted on the base plate 4 (the direction in which the semiconductor module 2 and the base plate 4 can be fitted to each other is limited to one direction), so that the erroneous mounting that the direction in which the semiconductor module 2 is mounted is different from the original direction can be prevented.

As described above, according to the third preferred embodiment, both the positioning of the semiconductor module 2 and the prevention of the erroneous mounting of the semiconductor module 2 can be achieved.

### Fourth Preferred Embodiment

### <Configuration>

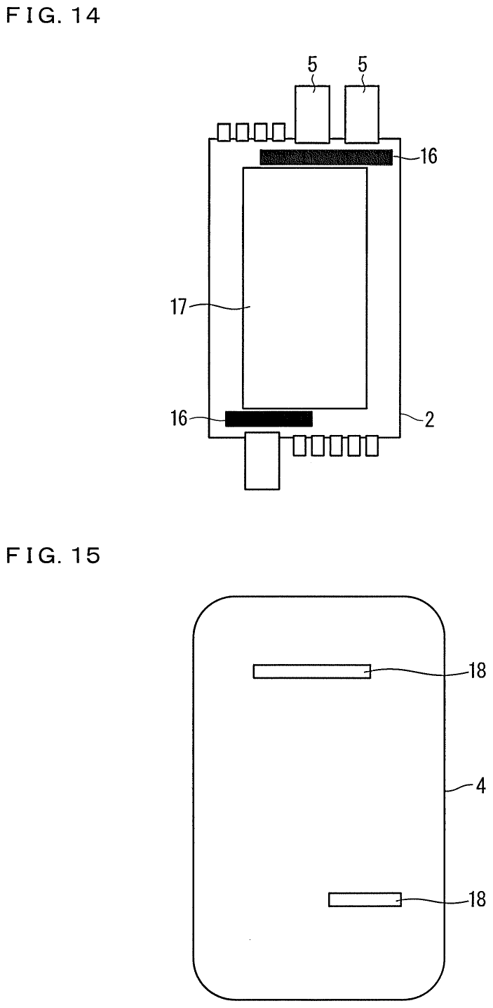

FIG. 14 is a view illustrating an example of a configuration of the semiconductor module 2 according to the fourth preferred embodiment, and illustrates a back surface of the semiconductor module 2.

The semiconductor module 2 includes linear protrusions 16 on two opposing sides. Although FIG. 14 illustrates the case where the linear protrusions 16 are provided on two opposing sides of the semiconductor module 2, the linear protrusions 16 may be provided on one side. That is, the semiconductor module 2 includes the linear protrusion 16 on at least one side.

The linear protrusion 16 is provided between the electrode terminal 5 and a connection portion 17. The connection portion 17 is a portion that connects the semiconductor module 2 and the base plate 4, and is a portion to which heat transfer grease, solder, or sinter is applied.

The linear protrusions 16 are provided so as not to be point-symmetric with respect to the center of the semiconductor module 2 (the center of the semiconductor module 2 in plan view illustrated in FIG. 14). In the semiconductor module 2 illustrated in FIG. 14, the protrusions 16 provided on two opposing sides are provided so as not to be point-symmetric with respect to the center of the semiconductor module 2. When the protrusions 16 are provided on one side of the semiconductor module 2, the protrusions 16 are provided so as not to be point-symmetric with respect to the center of the semiconductor module 2.

FIG. 15 is a view illustrating a configuration of the base plate 4. The base plate 4 includes a recess 18 that is provided so as to correspond to the protrusion 16 of the semiconductor module 2. When the semiconductor module 2 is mounted on the base plate 4, the protrusion 16 of the semiconductor module 2 and the recess 18 of the base plate 4 are fitted to each other. Thus, the semiconductor module 2 is positioned.

### <Effect>

In the case where conductive heat transfer grease, solder, or sinter is used to connect the semiconductor module 2 and the base plate 4, when the conductive heat transfer grease, solder, or sinter flows out to the vicinity of the electrode terminal 5 of the semiconductor module 2, an insulation distance becomes insufficient, and sometimes the semiconductor module 2 cannot be attached to the base plate 4. As a countermeasure against this problem, the connection portion 17 to which the heat transfer grease, solder, or thinner is applied and the electrode terminal 5 are separated from each other by fitting the protrusion 16 of the semiconductor module 2 and the recess 18 of the base plate 4 (positioning the semiconductor module 2) to each other. Thus, the heat transfer grease, solder, or sinter can be prevented from flowing out to the vicinity of the electrode terminal 5.

In addition, because the protrusion 16 of the semiconductor module 2 is provided so as not to be point-symmetric with respect to the center of the semiconductor module 2, the direction is limited to one direction (the direction in which the semiconductor module 2 and the base plate 4 can be fitted is limited to one direction) when the semiconductor module 2 is mounted on the base plate 4, so that the erroneous mounting that the direction in which the semiconductor module 2 is mounted is different from the original direction can be prevented.

As described above, according to the fourth preferred embodiment, in addition to achieving both the positioning of the semiconductor module 2 and the prevention of the erroneous mounting of the semiconductor module 2, the heat transfer grease, solder, or sinter can be prevented from flowing out to the vicinity of the electrode terminal 5.

### Fifth Preferred Embodiment

### <Configuration>

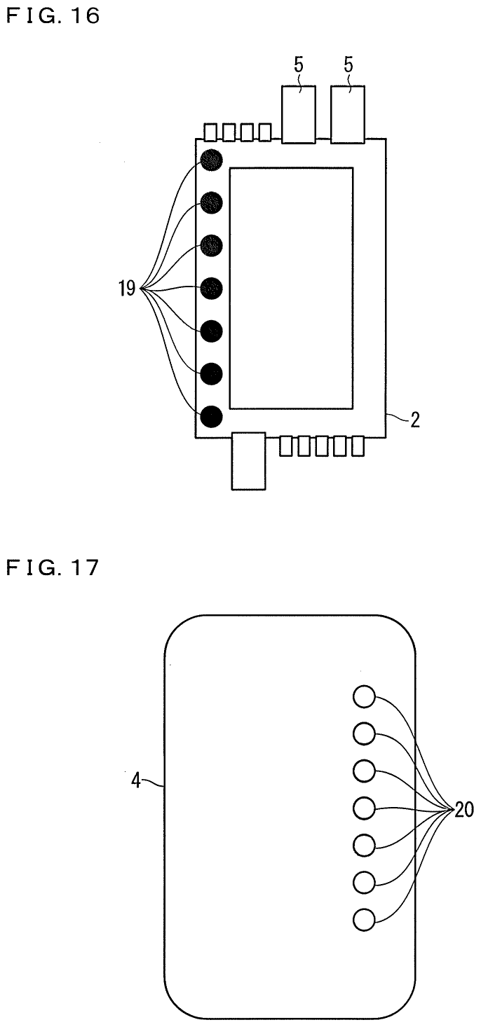

FIG. 16 is a view illustrating an example of a configuration of a semiconductor module 2 according to the fifth preferred embodiment, and illustrates a back surface of the semiconductor module 2.

The semiconductor module 2 includes at least three circular protrusions 19 on one side. Although FIG. 16 illustrates the case where at least three circular protrusions 19 are provided on one side of the semiconductor module 2, at least three circular protrusions 19 may be provided on the other side, or at least three circular protrusions 19 may be provided on a plurality of sides of the semiconductor module 2. That is, the semiconductor module 2 includes at least three circular protrusions 19 on at least one side.

The at least three circular protrusions 19 are provided so as not to be point-symmetric with respect to the center of the semiconductor module 2 (the center of the semiconductor module 2 in plan view illustrated in FIG. 16). The protrusion 19 of the semiconductor module 2 in FIG. 16 is provided on one side of the semiconductor module 2 so as not to be point-symmetric with respect to the center of the semiconductor module 2. In addition, when the protrusions 19 are provided on a plurality of sides of the semiconductor module 2, these protrusions 19 are required to be provided so as not to be point-symmetric with respect to the center of the semiconductor module 2.

FIG. 17 is a view illustrating a configuration of the base plate 4. The base plate 4 includes a recess 20 that is provided so as to correspond to the protrusion 19 of the semiconductor module 2. When the semiconductor module 2 is mounted on the base plate 4, the protrusion 19 of the semiconductor module 2 and the recess 20 of the base plate 4 are fitted to each other. Thus, the semiconductor module 2 is positioned.

### <Effect>

In the first preferred embodiment, when a part of the linear protrusion 8 is lost as illustrated in FIG. 13, the positional displacement is generated when the semiconductor module 2 is mounted on the base plate 4, so that the semiconductor module 2 and the base plate 4 cannot be fixed so as not to be displaced.

On the other hand, in the fifth preferred embodiment, even when one of the protrusions 19 is lost, the remaining protrusions 19 can be fitted into the recesses 20 of the base plate 4 (the semiconductor module 2 can be positioned) by providing at least three protrusions 19 of the semiconductor module 2.

In addition, because the protrusion 19 of the semiconductor module 2 is provided so as not to be point-symmetric with respect to the center of the semiconductor module 2, the direction is limited to one direction when the semiconductor module 2 is mounted on the base plate 4 (the direction in which the semiconductor module 2 and the base plate 4 can be fitted is limited to one direction), so that the erroneous mounting that the direction in which the semiconductor module 2 is mounted is different from the original direction can be prevented.

As described above, according to the fifth preferred embodiment, both the positioning of the semiconductor module 2 and the prevention of erroneous mounting of the semiconductor module 2 can be achieved.

### Sixth Preferred Embodiment

### <Configuration>

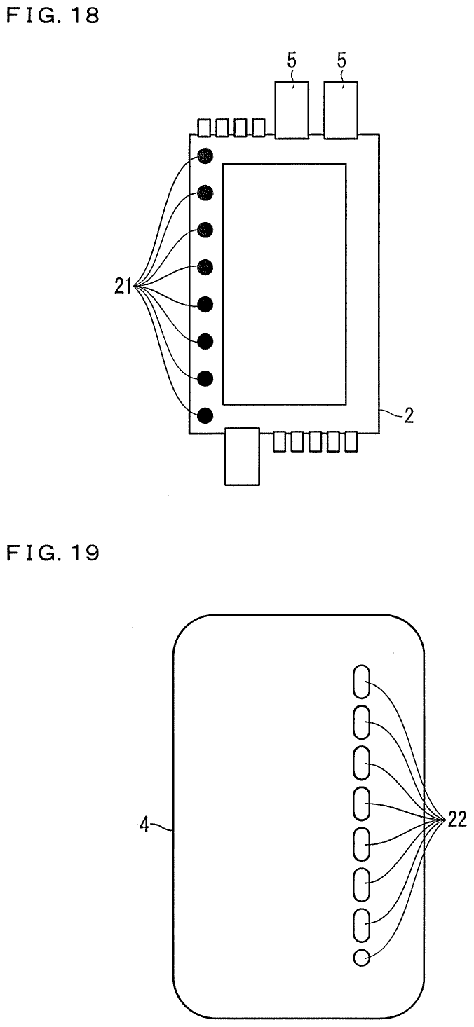

FIG. 18 is a view illustrating an example of a configuration of a semiconductor module 2 according to the sixth preferred embodiment, and illustrates a back surface of the semiconductor module 2.

The semiconductor module 2 includes at least three circular protrusions 21 on one side. Although FIG. 18 illustrates the case where at least three circular protrusions 21 are provided on one side of the semiconductor module 2, at least three circular protrusions 21 may be provided on the other side, or at least three circular protrusions 21 may be provided on a plurality of sides of the semiconductor module 2. That is, the semiconductor module 2 includes at least three circular protrusions 21 on at least one side.

The at least three circular protrusions 21 are provided so as not to be point-symmetric with respect to the center of the semiconductor module 2 (the center of the semiconductor module 2 in plan view illustrated in FIG. 18). The protrusions 21 of the semiconductor module 2 in FIG. 18 are provided on one side of the semiconductor module 2 so as not to be point-symmetric with respect to the center of the semiconductor module 2. In addition, when the protrusions 21 are provided on a plurality of sides of the semiconductor module 2, these protrusions 21 are required to be provided so as not to be point-symmetric with respect to the center of the semiconductor module 2.

FIG. 19 is a view illustrating a configuration of the base plate 4. The base plate 4 includes a recess 22 that is provided so as to correspond to the protrusion 21 of the semiconductor module 2. Among the recesses 22, only one recess 22 has a circular shape, and other recesses 22 have an elliptical shape. When the semiconductor module 2 is mounted on the base plate 4, the protrusion 21 of the semiconductor module 2 and the recess 22 of the base plate 4 are fitted to each other. Thus, the semiconductor module 2 is positioned.

### <Effect>

The semiconductor module 2 and the base plate 4 have different thermal expansion coefficients, and there is a difference in expansion and contraction depending on the thermal histories of the semiconductor module 2 and the base plate 4. In the sixth preferred embodiment, because only one recess 22 of the recesses 22 of the base plate 4 has a circular shape and other recesses 22 has an elliptical shape, the difference in expansion and contraction due to the thermal history of each of the semiconductor module 2 and the base plate 4 can be absorbed, and the protrusion 21 of the semiconductor module 2 can be prevented from being damaged due to the thermal history.

In addition, because the protrusion 21 of the semiconductor module 2 is provided so as not to be point-symmetric with respect to the center of the semiconductor module 2, the direction is limited to one direction when the semiconductor module 2 is mounted on the base plate 4 (the direction in which the semiconductor module 2 and the base plate 4 can be fitted is limited to one direction), so that the erroneous mounting that the direction in which the semiconductor module 2 is mounted is different from the original direction can be prevented.

As described above, according to the sixth preferred embodiment, both the positioning of the semiconductor module 2 and the prevention of the erroneous mounting of the semiconductor module 2 can be achieved.

### Seventh Preferred Embodiment

### <Configuration>

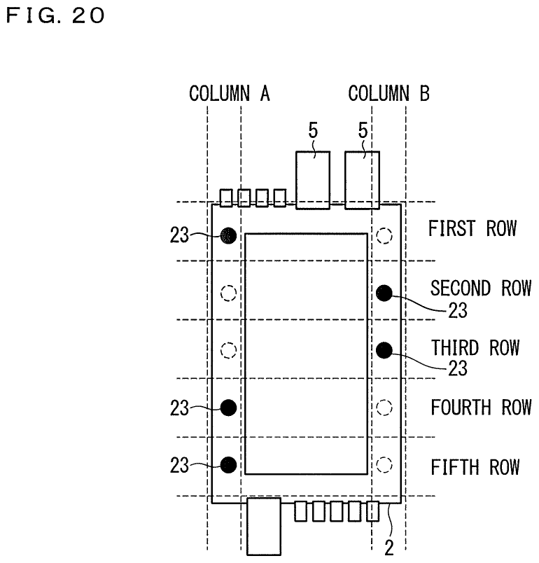

FIG. 20 is a view illustrating an example of a configuration of a semiconductor module 2 according to the seventh preferred embodiment, and illustrates a back surface of the semiconductor module 2.

The semiconductor module 2 includes at least two circular protrusions 23 provided on each of two opposing sides so as not to be opposite to each other.

In the example of FIG. 20, the circular protrusion 23 is provided in a first row, a fourth row, and a fifth row in a column A, and is provided in a second row and a third row in a column B. As described above, the circular protrusion 23 is not provided in the same row in each of the columns A and B. Dashed circles illustrated in the columns A and B of FIG. 20 indicate that unevenness is not provided.

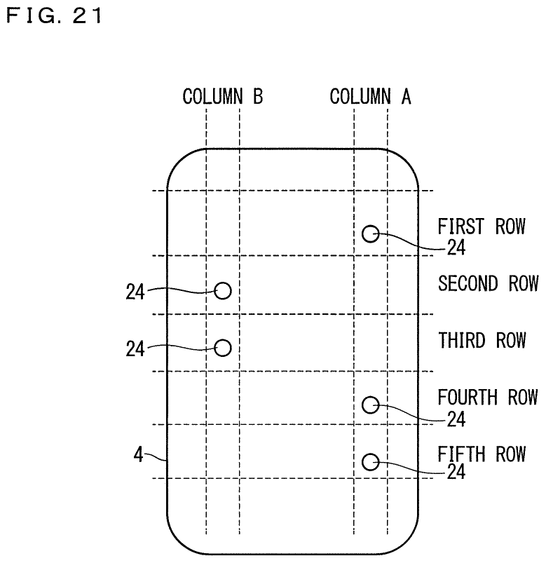

FIG. 21 is a view illustrating a configuration of the base plate 4. The base plate 4 includes a recess 24 that is provided so as to correspond to the protrusion 23 of the semiconductor module 2. When the semiconductor module 2 is mounted on the base plate 4, the protrusion 23 of the semiconductor module 2 and the recess 24 of the base plate 4 are fitted to each other. Thus, the semiconductor module 2 is positioned.

### <Effect>

According to the seventh preferred embodiment, when the semiconductor module 2 is mounted on the base plate 4, the protrusion 23 of the semiconductor module 2 and the recess 24 of the base plate 4 are fitted to each other, so that the semiconductor module 2 can be positioned.

In addition, because the protrusion 23 of the semiconductor module 2 is provided so as not to be opposite to each other on each of the two opposing sides, the direction is limited to one direction when the semiconductor module 2 is mounted on the base plate 4 (the direction in which the semiconductor module 2 and the base plate 4 can be fitted is limited to one direction), so that the erroneous mounting that the direction in which the semiconductor module 2 is mounted is different from the original direction can be prevented.

Furthermore, according to the seventh preferred embodiment, a type of the semiconductor module 2 can be identified. For example, when the number of protrusions 23 provided in the semiconductor module 2 is at least two and when the number of rows is five, 5C2+5C3=20 ways of identification can be performed. Thus, a rated current, a rated voltage, a circuit configuration, or the like of the semiconductor module 2 can be identified.

As an example, it is assumed that the protrusion 23 (two protrusions 23 in the column A and three protrusions 23 in the column B) provided in the semiconductor module 2 having the rated current of 100 A and the rated voltage of 650 V is fitted into the recess 24 of the base plate 4. In this case, the protrusion 23 (three protrusions 23 in the column A and two protrusions 23 in the column B) provided in the semiconductor module 2 having the rated current of 50 A and the rated voltage of 1200 V is not fitted into the recess 24 of the base plate 4.

When the protrusion 23 is provided in each of the same rows of the columns A and B in the semiconductor module 2, the recess 24 in each of the same rows of the columns A and B also in the base plate 4 is required to be provided. In this case, also in the semiconductor module 2 in which the protrusion 23 is provided only in the column A in the same row and the semiconductor module 2 in which the protrusion 23 is provided only in the column B in the same row, because each protrusion 23 can be fitted into the recess 24 of the base plate 4, the type of the semiconductor module 2 cannot be identified. Accordingly, in the semiconductor module 2, the protrusion 23 is not provided in each of the same rows of the column A and the column B.

As described above, according to the seventh preferred embodiment, the type of the semiconductor module 2 can be identified in addition to both the positioning of the semiconductor module 2 and the prevention of the erroneous mounting of the semiconductor module 2.

### Eighth Preferred Embodiment

### <Configuration>

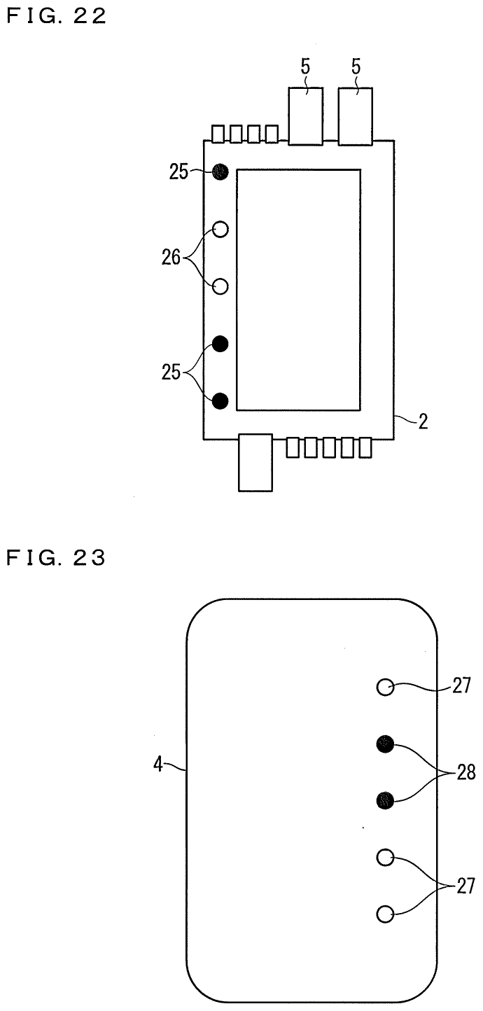

FIG. 22 is a view illustrating an example of a configuration of a semiconductor module 2 according to the eighth preferred embodiment, and illustrates a back surface of the semiconductor module 2.

The semiconductor module 2 includes at least two circular protrusions 25 and at least two circular recesses 26 on one side. In the example of FIG. 22, the semiconductor module 2 includes three protrusions 25 and two recesses 26.

Although FIG. 22 illustrates the case where at least two circular protrusions 25 and at least two circular recesses 26 are provided on one side of the semiconductor module 2, at least two circular protrusions 25 and at least two circular recesses 26 may be provided on other side, or at least two circular protrusions 25 and at least two circular recesses 26 may be provided on a plurality of sides of the semiconductor module 2. That is, the semiconductor module 2 includes at least two circular protrusions 25 and at least two circular recesses 26 on at least one side.

The at least two circular protrusions 25 and the at least two circular recesses 26 are provided so as not to be point-symmetric with respect to the center of the semiconductor module 2 (the center of the semiconductor module 2 in plan view illustrated in FIG. 22). The protrusions 25 and the recesses 26 of the semiconductor module 2 in FIG. 22 are provided on one side of the semiconductor module 2 so as not to be point-symmetric with respect to the center of the semiconductor module 2. In addition, when the protrusions 25 and the recesses 26 are provided on the plurality of sides of the semiconductor module 2, the protrusions 25 and the recesses 26 are required to be provided so as not to be point-symmetric with respect to the center of the semiconductor module 2.

FIG. 23 is a view illustrating a configuration of the base plate 4. The base plate 4 includes a recess 27 that is provided so as to correspond to the protrusion 25 of the semiconductor module 2 and a protrusion 28 that is provided so as to correspond to the recess 26. When the semiconductor module 2 is mounted on the base plate 4, the protrusion 25 of the semiconductor module 2 and the recess 27 of the base plate 4 are fitted to each other, and the recess 26 of the semiconductor module 2 and the protrusion 28 of the base plate 4 are fitted to each other. Thus, the semiconductor module 2 is positioned.

### <Effect>

According to the eighth preferred embodiment, when the semiconductor module 2 is mounted on the base plate 4, the protrusion 25 of the semiconductor module 2 and the recess 27 of the base plate 4 are fitted to each other, and the recess 26 of the semiconductor module 2 and the protrusion 28 of the base plate 4 are fitted to each other, so that the semiconductor module 2 can be positioned.

In addition, because the protrusions 25 and the recesses 26 of the semiconductor module 2 are provided so as not to be point-symmetric with respect to the center of the semiconductor module 2, the direction is limited to one direction when the semiconductor module 2 is mounted on the base plate 4 (the direction in which the semiconductor module 2 and the base plate 4 can be fitted is limited to one direction), so that the erroneous mounting that the direction in which the semiconductor module 2 is mounted is different from the original direction can be prevented.

Furthermore, according to the eighth preferred embodiment, the type of the semiconductor module 2 can be identified. For example, in the case where a total of five protrusions 25 and recesses 26 are provided on one side of the semiconductor module 2, 5C5+5C4+5C3+5C2+5C1+5C0=32 ways can be identified. Thus, a rated current, a rated voltage, a circuit configuration, or the like of the semiconductor module 2 can be identified.

As an example, it is assumed that two protrusions 25 and three recesses 26 provided in the semiconductor module 2 having the rated current of 100 A and the rated voltage of 650 V are fitted to each of the recesses 27 and the protrusions 28 of the base plate 4. In this case, the three protrusions 25 and the two recesses 26 provided in the semiconductor module 2 having the rated current of 50 A and the rated voltage of 1200 V are not fitted into the recesses 27 and the protrusions 28 of the base plate 4, respectively.

As described above, according to the eighth preferred embodiment, the type of the semiconductor module 2 can be identified in addition to both the positioning of the semiconductor module 2 and the prevention of the erroneous mounting of the semiconductor module 2.

In the semiconductor module 2 (see FIG. 18) according to the sixth preferred embodiment, at least two protrusions 21 may be replaced with recesses 26. In this case, a protrusion 28 corresponding to the recess 26 of the semiconductor module 2 is required to be provided in the base plate 4.

In addition, in the semiconductor module 2 according to the seventh preferred embodiment (see FIG. 20), the recess 26 may be provided at the position of the dashed circle illustrated in the column A and the column B. In this case, a protrusion 28 corresponding to the recess 26 of the semiconductor module 2 is required to be provided in the base plate 4.

In the present disclosure, each preferred embodiment can be freely combined, and each preferred embodiment can be appropriately modified or omitted within the scope of the disclosure.

### <Appendixes>

Hereinafter, various aspects of the present disclosure will be collectively described as appendixes.

### (Appendix 1)

A semiconductor device includes:
a semiconductor module; and
a base plate on which the semiconductor module is mounted,
in which the semiconductor module includes a linear protrusion that is provided so as not to be point-symmetric with respect to a center of the semiconductor module on at least one side, and
the base plate includes a recess that is provided so as to correspond to the protrusion.

### (Appendix 2)

A semiconductor device includes:
a semiconductor module; and
a base plate on which the semiconductor module is mounted,
in which the semiconductor module includes protrusions that are provided at both ends of at least one side so as not to be point-symmetric with respect to a center of the semiconductor module, and
the base plate includes a circular recess that is provided so as to correspond to the protrusion at one end of the both ends and an elliptical recess that is provided so as to correspond to the protrusion at the other end of the both ends.

### (Appendix 3)

A semiconductor device includes:
a semiconductor module; and
a base plate on which the semiconductor module is mounted,
in which the semiconductor module includes an L-shaped protrusion that is provided so as not to be point-symmetric with respect to a center of the semiconductor module in at least one corner, and
the base plate includes an L-shaped recess that is provided so as to correspond to the protrusion.

### (Appendix 4)

A semiconductor device includes:
a semiconductor module; and
a base plate on which the semiconductor module is mounted;
in which the semiconductor module includes a linear protrusion that is provided so as not to be point-symmetric with respect to a center of the semiconductor module between a terminal that protrudes outward from the semiconductor module and a connection portion that connects the semiconductor module and the base plate, the linear protrusion being provided on at least one side, and
the base plate includes a recess that is provided so as to correspond to the protrusion.

### (Appendix 5)

A semiconductor device includes:
a semiconductor module; and
a base plate on which the semiconductor module is mounted;
in which the semiconductor module includes at least three circular protrusions that are provided so as not to be point-symmetric with respect to a center of the semiconductor module on at least one side, and
the base plate includes at least three recesses that are provided so as to correspond to the protrusions.

### (Appendix 6)

The semiconductor device described in Appendix 5, in which only one of the recesses is circular, and other recesses are elliptical.

### (Appendix 7)

The semiconductor device described in Appendix 5 or 6, in which the semiconductor module further includes at least two circular recesses on the at least one side, and
the base plate further includes at least two circular protrusions that are provided so as to correspond to the recesses.

### (Appendix 8)

A semiconductor device includes:
a semiconductor module; and
a base plate on which the semiconductor module is mounted;
in which the semiconductor module includes at least two circular protrusions that are provided so as not to be opposite to each other on each of two opposing sides, and
the base plate includes at least two recesses that are provided so as to correspond to the protrusions.

### (Appendix 9)

The semiconductor device described in Appendix 8, in which the semiconductor module further includes at least two circular recesses on at least one of the two opposing sides, and
the base plate further includes at least two circular protrusions that are provided so as to correspond to the recesses.

While the disclosure has been shown and described in detail, the foregoing description is in all aspects illustrative and not restrictive. It is therefore understood that numerous modifications and variations can be devised.

What is claimed is:

1. A semiconductor device comprising:
a semiconductor module; and
a base plate on which the semiconductor module is mounted,
wherein the semiconductor module includes a linear protrusion that is provided so as not to be point-symmetric with respect to a center of the semiconductor module on at least one side, and
the base plate includes a recess that is provided so as to correspond to the protrusion.

2. A semiconductor device comprising:
a semiconductor module; and
a base plate on which the semiconductor module is mounted,
wherein the semiconductor module includes protrusions that are provided at both ends of at least one side so as not to be point-symmetric with respect to a center of the semiconductor module, and
the base plate includes a circular recess that is provided so as to correspond to the protrusion at one end of the both ends and an elliptical recess that is provided so as to correspond to the protrusion at the other end of the both ends.

3. A semiconductor device comprising:
a semiconductor module; and
a base plate on which the semiconductor module is mounted,
wherein the semiconductor module includes an L-shaped protrusion that is provided so as not to be point-symmetric with respect to a center of the semiconductor module in at least one corner, and
the base plate includes an L-shaped recess that is provided so as to correspond to the protrusion.

4. A semiconductor device comprising:
a semiconductor module; and
a base plate on which the semiconductor module is mounted;
wherein the semiconductor module includes a linear protrusion that is provided so as not to be point-symmetric with respect to a center of the semiconductor module between a terminal that protrudes outward from the semiconductor module and a connection portion that connects the semiconductor module and the base plate, the linear protrusion being provided on at least one side, and
the base plate includes a recess that is provided so as to correspond to the protrusion.

5. A semiconductor device comprising:
a semiconductor module; and
a base plate on which the semiconductor module is mounted;
wherein the semiconductor module includes at least three circular protrusions that are provided so as not to be point-symmetric with respect to a center of the semiconductor module on at least one side, and
the base plate includes at least three recesses that are provided so as to correspond to the protrusions.

6. The semiconductor device according to claim 5, wherein only one of the recesses is circular, and other recesses are elliptical.

7. The semiconductor device according to claim 5, wherein the semiconductor module further includes at least two circular recesses on the at least one side, and
the base plate further includes at least two circular protrusions that are provided so as to correspond to the recesses.

8. The semiconductor device according to claim 6, wherein the semiconductor module further includes at least two circular recesses on the at least one side, and
the base plate further includes at least two circular protrusions that are provided so as to correspond to the recesses.

9. A semiconductor device comprising:
a semiconductor module; and
a base plate on which the semiconductor module is mounted;
wherein the semiconductor module includes at least two circular protrusions that are provided so as not to be opposite to each other on each of two opposing sides, and
the base plate includes at least two recesses that are provided so as to correspond to the protrusions.

10. The semiconductor device according to claim 9, wherein the semiconductor module further includes at least two circular recesses on at least one of the two opposing sides, and
the base plate further includes at least two circular protrusions that are provided so as to correspond to the recesses.
